(19) United States
(12) Patent Application Publication
(10) Pub. No.: US 2012/0074404 A1
(43) Pub. Date: Mar. 29, 2012

(54) SUPPORTING SUBSTRATE, BONDED SUBSTRATE, METHOD FOR MANUFACTURING SUPPORTING SUBSTRATE, AND METHOD FOR MANUFACTURING BONDED SUBSTRATE

(75) Inventor: Kazuhiro Ushita, Tokyo (JP)

(73) Assignee: BRIDGESTONE CORPORATION, Chuo-ku, Tokyo (JP)

(21) Appl. No.: 13/262,153

(22) PCT Filed: Mar. 19, 2010
(86) PCT No.: PCT/JP2010/054859

§ 371 Date: Nov. 23, 2011

(30) Foreign Application Priority Data
Mar. 31, 2009 (JP) 2009-085294

(51) Int. Cl. H01L 29/24; H01L 21/18; H01L 21/20

(52) U.S. Cl. 257/51; 438/478; 438/459; 257/E29.104; 257/E21.09; 257/E21.087

(57) ABSTRACT

Provided is a supporting substrate (30) to be bonded on a single crystalline wafer composed of a single crystalline body. The supporting substrate is provided with a silicon carbide polycrystalline substrate (10) composed of a silicon carbide polycrystalline body, and a coat layer (20) deposited on the silicon carbide polycrystalline substrate (10). The coat layer (20) is composed of silicon carbide or silicon and is in contact with the single crystalline wafer, and the arithmetic average roughness of the contact surface (22) of the coat layer (20) in contact with the single crystalline wafer is 1 nm or less.

### TECHNICAL FIELD

The present invention relates to a bonded substrate having a single crystalline wafer made of a single crystalline body and a supporting substrate to be bonded on the single crystalline wafer, the supporting substrate constituting the bonded substrate; a method for manufacturing the supporting substrate; and a method for manufacturing the bonded substrate.

### BACKGROUND ART

Conventionally, it is found that a single crystalline body consisting of silicon, silicon carbide, gallium nitride, aluminum nitride or the like has its superior high frequency properties as well as its superior heat resistance or withstand voltage. Thus, a wafer made of these single crystal bodies (hereinafter, appropriately abbreviated as a single crystalline wafer) is widely known as a semiconductor material to be employed in an LED device, a power device, or a high frequency device of a next generation (for example, Patent Document 1).

Such a single crystalline wafer has its superior properties, whereas its related manufacturing method is complicated and its related price is high. Therefore, a so called bonded substrate, which is obtained by bonding a supporting substrate for supporting a single crystalline wafer and a thin-filmed single crystalline wafer with each other, is widely known. As a method for bonding a single crystalline wafer and a supporting substrate with each other without using an adhesive agent, for example, there is proposed a heating and pressurization bonding method, a surface activation bonding method with ion beam irradiation onto a bonding face, or a bonding method via a hydrophilic group with hydrophilizing treatment and the like.

Such a bonded substrate functions as a material for semiconductor device fabrication by disposing a single crystalline wafer at a site at which the substrate is utilized as a semiconductor material. In addition, such a bonded substrate ensures its required substrate thickness and strength on use by means of a supporting substrate.

### PRIOR ART DOCUMENT

### Patent Document

Patent Document 1: JP-A-2005-8472 (Pages 4 to 6)

### SUMMARY OF THE INVENTION

The conventional bonded substrate described above has entailed the following problem. That is, in a case where a supporting substrate is manufactured by means of sintering treatment, since air holes are formed on the supporting substrate, irregularities are formed on a surface of the supporting substrate. Therefore, if the supporting substrate is bonded on a single crystalline wafer, a gap is formed between the single crystalline wafer and the supporting substrate, the bonding faces do not come into intimate contact with each other sufficiently, and there has been a problem that a sufficient bonding strength is not obtained.

Accordingly, it is an object of the present invention or provide a supporting substrate to be bonded on a single crystalline wafer, which is capable of restraining a gap to be formed between the single crystalline wafer and the supporting substrate, a bonded substrate, a method for manufacturing the supporting substrate, and a method for manufacturing the bonded substrate.

To solve the above problems, the present invention has following feature. First, a first aspect or the present invention is summarized as a supporting substrate (supporting substrate 30) to be bonded on a single crystalline wafer (single crystalline wafer 50) made of a single crystalline body, the supporting substrate including: a silicon carbide polycrystalline substrate (silicon carbide polycrystalline substrate 10) made of a silicon carbide polycrystalline body; and a coating layer (coating layer) to be evaporated on the silicon carbide polycrystalline body, wherein the coating layer is made of silicon carbide or silicon, and comes into contact with the single crystalline wafer, and an arithmetic average roughness of a surface of the coating layer that comes into contact with the single crystalline wafer is 1 nanometer or less.

Such a supporting substrate is provided with a coating layer made of silicon carbide or silicon between a silicon carbide polycrystalline substrate and a single crystalline wafer. Since an arithmetic average roughness of a surface of a coating layer coming into contact with the single crystalline wafer is 1 nanometer or less, it is possible to restrain a gap from being formed between the coating layer and the single crystalline wafer.

Therefore, the supporting substrate is capable of restraining a gap from being formed between the single crystalline wafer and the supporting substrate.

A second feature of the present invention according to the first feature is summarized as that the coating layer is evaporated on the silicon carbide polycrystalline substrate by means of a physical vapor deposition method or a chemical vapor deposition method.

A third feature of the present invention according to the first or second feature is summarized as that a thickness of the coating layer is 5 microns or more.

A fourth feature of the present invention is summarized as a bonded substrate (bonded substrate 100) including: a single crystalline wafer (single crystalline wafer 50) made of a single crystalline body; and a supporting substrate (supporting substrate 30) to be bonded on the single crystalline wafer, wherein the supporting substrate has: a silicon carbide polycrystalline substrate (silicon carbide polycrystalline substrate 10) made of a silicon carbide polycrystalline body; and a coating layer (coating layer 20) to be evaporated on the silicon carbide polycrystalline substrate, the coating layer is made of silicon carbide or silicon, and conies into contact with the single crystalline wafer, and an arithmetic average roughness of a surface of the coating layer that comes into contact with the single crystalline wafer is 1 nanometer or less.

A fifth feature of the present invention is summarized as a method for manufacturing a supporting substrate (supporting substrate 30) to be bonded on a single crystalline wafer (single crystalline wafer 5-) made of a single crystalline body, the method including the steps of: (step 1) evaporating silicon carbide or silicon on a silicon carbide polycrystalline substrate (silicon carbide polycrystalline substrate 10) made of a silicon carbide polycrystalline body; and (step 2) applying grinding onto a face onto which the evaporation is made, in the silicon carbide polycrystalline substrate, so as to allow an arithmetic average roughness of the evaporated face to be 1 nanometer or less.

A sixth feature of the present invention is summarized as a method for manufacturing a bonded substrate (bonded substrate 100) which has a single crystalline wafer (single crystalline wafer 50) made of a single crystalline body and a bonded substrate to be bonded on the single crystalline wafer, the method comprising the steps of: (step 1) evaporating silicon carbide or silicon on a silicon carbide polycrystalline substrate (silicon carbide polycrystalline substrate 10) made of a silicon carbide polycrystalline body; (step 2) applying grinding onto a face onto which the evaporation is made, in the silicon carbide polycrystalline substrate, so as to allow an arithmetic average roughness of the evaporated face to be 1 nanometer or less; and (step 3) bonding a face to which the grinding is applied and the single crystalline wafer with each other.

According to the features of the present invention, provided are a supporting substrate to be bonded on a single crystalline wafer, which is capable of restraining a gap to be formed between the single crystalline wafer and the supporting substrate, a bonded substrate, a method for manufacturing the supporting substrate, and a method for manufacturing the bonded substrate.

### BRIEF DESCRIPTION OF THE DRAWINGS

FIG. 1 is a perspective view of a bonded substrate according to an embodiment of the present invention.

FIG. 2 is a sectional view of a supporting substrate according to an embodiment of the present invention.

FIG. 3 is a flowchart showing a method for manufacturing the support substrate, according to an embodiment of the present invention,

FIG. 4 is a view showing a method for manufacturing the support substrate, according to an embodiment of the present invention.

FIG. 5 is a flowchart showing a method for manufacturing the bonded substrate, according to an embodiment of the present invention.

### BEST MODES FOR CARRYING OUT THE INVENTION

Next, a supporting substrate, a bonded substrate, a method for manufacturing the supporting substrate, and a method for manufacturing the bonded substrate, according to the present invention, will be described with reference to the drawings. Specifically, the above descriptions will be furnished as to (1) Entire Structure of Bonded substrate, (2) Detailed Description of Structure of Supporting Substrate, (3) Method for Manufacturing Supporting Substrate, (4) Method for Manufacturing Bonded substrate, (5) Comparative Evaluation, (6) Functions and Advantageous Effects, and (7) Other Embodiments.

In the following description of the drawings, the same constituent elements are designated by the same reference numerals. However, it should be kept in mind that the drawings are merely schematically shown, and the ratios of each dimension or the like are different from the real ones.

Therefore, specific dimensions, etc., should be determined in consideration of the following description. Of course, constituent elements with their different dimensional interrelationships and ratios are included in the respective drawings as well.

### (1) Entire Structure of Bonded Substrate

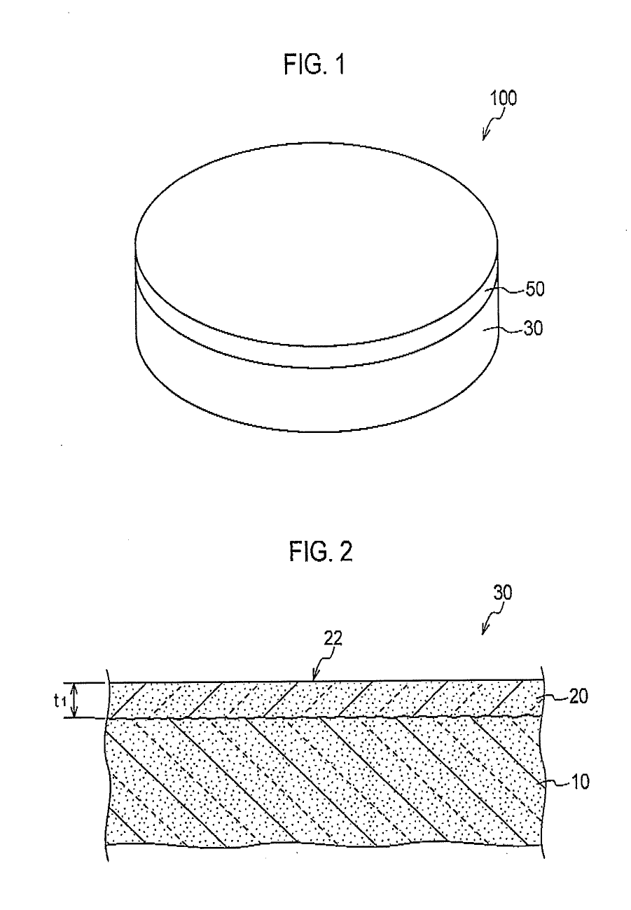

FIG. 1 is a perspective view of a bonded substrate 100 according to an embodiment of the present invention. As shown in FIG. 1, the bonded substrate is provided with: a single crystalline wafer 50 made of a single crystalline body; and a supporting substrate 30 to be bonded on the single crystalline wafer 50. Specifically, the single crystalline wafer 50 is made of a single crystalline body consisting of Si, GaN, SiC, AlN or the like.

The bonded substrate 100 is employed as a semiconductor device substrate such as an LED device, a power device, or a high frequency device of a next generation. The bonded substrate 100 ensures its required substrate thickness and strength on use by means of the supporting substrate 30.

### (2) Detailed Description of Structure of Supporting Substrate

FIG. 2 is a sectional view of a supporting substrate 30 according to an embodiment of the present invention. As shown in FIG. 2, the supporting substrate 30 is provided with: a silicon carbide Polycrystalline substrate 10 made of a polycrystalline body consisting of silicon carbide; and a coating layer 20 to be evaporated on the silicon carbide polycrystalline substrate 10.

The silicon carbide polycrystalline substrate 10 is made of a polycrystalline body consisting of silicon carbide, which can be inexpensively manufactured by means of sintering treatment such as hot press.

The coating layer 20 is made of silicon carbide or silicon, and is provided with a contact face 22 that comes into contact with the single crystalline wafer 50. The coating layer 20 is evaporated on the silicon carbide polycrystalline substrate 10, and thereafter, the evaporated coating layer is ground. Specifically, the coating layer 20 is evaporated on the silicon carbide polycrystalline substrate 10 by means of a physical vapor deposition method, a chemical vapor deposition method, or any other evaporation method or plating treatment and the like.

An average in thickness t1 of the coating layer 20, which is a thickness in the growth direction of the coating layer 20, is 5 microns or more or 10 microns or less. A surface of the coating layer 20 that comes into contact with the single crystalline wafer 50, namely, an arithmetical average roughness Ra of a contact face 22 is 1 nanometer or less.

A planer precision of the contact face 22 is 30 microns or less. Specifically, a BOW that is indicative of a difference in center face of the single crystalline wafer 50 from a reference face and a WARP that is indicative of a difference between a maximum value and a minimum value in distance from a best fit reference face of a center face that is obtained by compensating for a deformation component due to a self-weight up to a center face of the single crystalline wafer 50, in a state in which the contact face 22 is neither adsorbed nor fixed, are respectively 30 microns or less.

### (3) Method for Manufacturing Supporting Substrate

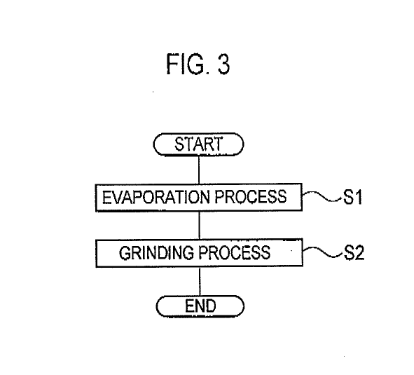

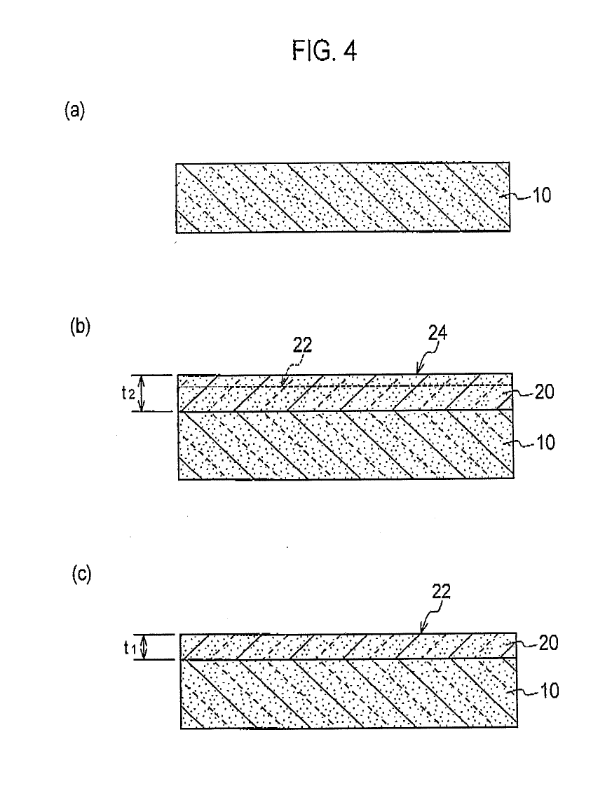

Next, a method for manufacturing a supporting substrate, according to the embodiment, will be described with reference to FIGS. 3 and 4. FIG. 3 is a flowchart showing the method for manufacturing the supporting substrate, according to the embodiment. FIG. 4 is a sectional view of a substrate for indicating the method for manufacturing the supporting substrate, according to the embodiment. Specifically, the method for manufacturing the supporting substrate 30 includes the steps set forth in the sections (3. 1) Evaporation Process and (3. 2) Grinding Process.

### (3. 1) Evaporation Process

As shown in FIG. 3 and FIG. 4 (a) and (b), in the evaporation process of step S1, silicon carbide or silicon is evaporated on the silicon carbide polycrystalline substrate 10 made of a silicon carbide polycrystalline body, and the coating layer 20 made of thickness t2 (10 microns) is formed. Specifically, the coating layer 20 made of 5 microns or more is formed on the silicon carbide polycrystalline substrate 10 by means of a physical vapor deposition method, a chemical vapor deposition method, or any other evaporation method or plating treatment and the like.

### (3. 2) Grinding Process

As shown in FIG. 3 and FIG. 4 (c), in the grinding process of step S2, in the silicon carbide polycrystalline substrate 10, grinding is applied onto an evaporation face 24 of the coating layer 20 that is a face on which evaporation has been made. Specifically, mechanical grinding or chemical and mechanical grinding is applied onto the evaporation face 24 of the coating layer 20.

In the grinding process of step S2, an arithmetic average roughness of the evaporation face 24 is formed to be 1 nanometer or less by means of the abovementioned grinding to thereby form a contact face 22. The thickness t1 of the coating layer 20 onto which grinding is applied is 5 microns or more or 10 microns or less. A supporting substrate 30 is manufactured by means of the abovementioned process.

(4) Method for Manufacturing Bonded substrate

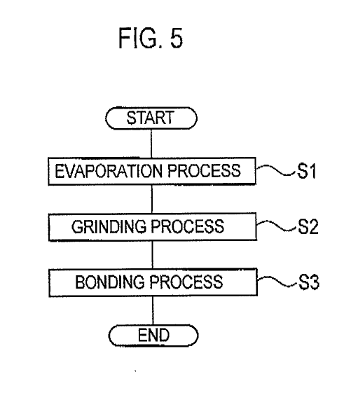

Next, a method for manufacturing a bonded substrate, according to the embodiment, will be described with reference to FIG. 5. FIG. 5 is a flowchart showing the method for manufacturing the bonded substrate, according to the embodiment.

Since descriptions of steps S1 and S2 are identical to those of the supporting substrate 30 described above, these descriptions are omitted here.

### (4. 1) Bonding Process

In the bonding step of step S3, faces onto which grinding is applied in the grinding step of step S2, i.e., the contact face 22 and the single crystalline wafer 50 are bonded with each other. A bonded substrate 100 is manufactured by means of the abovementioned process.

### (5) Comparative Evaluation

Next, comparative evaluation made by employing supporting substrates according to Comparative Examples and Working Example that follow will be described in order to further clarify advantageous effects of the present invention. Specifically, the above descriptions will be furnished as to (5. 1) Evaluation Method and (5. 2) Evaluation Result. It should be noted that the present invention is not limited by these examples.

### (5. 1) Evaluation Method

By employing supporting substrates of Comparative Examples and Working Example, the steps set forth in the sections (5. 1. 1) Observation of Surface State of Supporting Substrate and (5. 1. 2) Surface Roughness Evaluation, were performed. A specific description will be furnished as to the supporting substrates according to Comparative Examples and Working Example, which were employed in comparative evaluation. A diameter size of a wafer constituting the supporting substrates is 4 inches.

Each of the supporting substrates has its different structure of coating layer. Specifically, an arithmetic average roughness of a surface of the coating layer constituting a supporting substrate according to Working Example is 1 nanometer or less. A supporting substrate according to Comparative Example is not provided with a coating layer, and grinding is not applied onto a surface of a coating layer that constitutes a supporting substrate according to Comparative Example 2.

The supporting substrate according to Working Example is identical to the support substrate 30 according to the embodiment.

### (5. 1. 1) Observation of Surface State of Supporting Substrate

Observation method: Irregularities of a surface of each supporting substrate was observed by means of optical microscope.

### (5. 1. 2) Surface Roughness Evaluation

Evaluation method: Surface roughness of each support substrate was measured. Specifically, a computational average roughness Ra was specified.

### (5. 2) Evaluation Result

Evaluation results obtained by employing the supporting substrates according to Comparative Example 1, Comparative Example 2, and Working Example, mentioned above, will be described with reference to Table 1.

TABLE 1

| | Comparative | Comparative | Working |
|---|---|---|---|
| | Example 1 | Example 2 | Example |
| Observation by | Air holes are | Air holes are | No air holes |
| means of electronic | present. | present. | are present |
| microscope | | | |
| Arithmetic average | 1.5 | 10 to 100 | <1.0 |
| roughness Ra | nanometers | nanometers | nanometer |

On the supporting substrate according to Working Example, such air holes that had been observed on the supporting substrates according to Comparative Examples 1 and 2 were hardly observed, and the arithmetic average roughness also indicated a small value.

### (6) Functions and Advantageous Effects

As described above, such a support substrate 30 according to the embodiment is provided with a coating layer 20 made of silicon carbide or silicon between a silicon carbide polycrystalline substrate 10 and a single crystalline wafer 50. Since the arithmetic average roughness of the surface of the coating layer 20 that comes into contact with the single crystalline wafer 50 is 1 nanometer or less, it is possible to restrain a gap from being formed between the coating layer 20 and the single crystalline wafer 50. Therefore, the supporting substrate 30 is capable of restraining a gap from being formed between the single crystalline wafer 50 and the supporting substrate 30.

In a case where the arithmetic average roughness of the surface of the coating layer 20 that comes into contact with the single crystalline wafer 50 is greater than 1 nanometer, a gap is formed between the single crystalline wafer 50 and the supporting substrate 30. Accordingly, the bonding faces do not come into intimate contact with each other sufficiently, and a sufficient bonding strength is not obtained.

In the embodiment, since the silicon carbide polycrystalline substrate 10 can be manufactured by means of sintering treatment such as hot press, the supporting substrate 30 can be inexpensively manufactured.

In the embodiment, the coating layer 20 is evaporated on the silicon carbide polycrystalline substrate 10 by means of a physical vapor deposition method or a chemical vapor deposition method. Thus, the coating layer 20 has its heat resistance, and is fixedly adhered to the silicon carbide polycrystalline substrate 10.

In the embodiment, a thickness t1 of the coating layer 20 is 5 microns or more. Thus, a contact face 22 can be formed without being affected by irregularities of the surface of the silicon carbide polycrystalline substrate 10 on which the coating layer 20 is evaporated.

In the embodiment, the thickness t1 of the coating layer 20 is 10 microns or more. If thickness t1 of the coating layer 20 is greater than 10 microns, the manufacturing cost becomes high, which is not preferable.

In the embodiment, it is possible to restrain a gap from being formed between the single crystalline wafer 50 and the supporting substrate 30, and the bonded substrate 100 can be manufactured at a low cost by employing the supporting substrate 30 with its less gap.

In the embodiment, the bonded substrate 100 ensures its required substrate thickness and strength on use by means of the supporting substrate 30. In addition, since the silicon carbide polycrystalline substrate 10 constituting the supporting substrate 30 can be manufactured by means of sintering treatment, the supporting substrate 30 with its large aperture can be readily manufactured. Therefore, the bonded substrate 100 with its large aperture can be manufactured more readily than the single crystalline wafer that is entirely made of a single crystalline body.

In the embodiment, the method for manufacturing the supporting substrate 30 includes the step S1 of evaporating silicon carbide or silicon on the silicon carbide polycrystalline substrate 10 made of a silicon carbide polycrystalline body and the step S2 of applying grinding onto a face on which evaporation has been made on the silicon carbide polycrystalline substrate 10 and then forming the arithmetic average roughness of the face on which evaporation has been made to be 1 nanometer or less.

Thus, it is possible to restrain a gap that is formed relative to the single crystalline wafer 50, by means of a single method, in comparison with a method of bonding the conventional silicon carbide polycrystalline substrate 10 and the single crystalline wafer 50 with each other. In addition, it is possible to further restrain a gap relative to the single crystalline wafer 50 by applying grinding onto the face on which evaporation has been made.

In the embodiment, the coating layer 20 is made of silicon carbide or silicon. Therefore, the coating layer 20 has its properties that its heat conductivity is high, its temperature is likely to lower from a high temperature, and its heat resistance is superior.

### (7) Other Embodiments

As described above, while the contents of the present invention were disclosed through the embodiments of the present invention, it should not be apprehended that the discussion and drawings forming a part of this disclosure limits the present invention. From this disclosure, a variety of substitutive embodiments, examples, and operational techniques would have been self-evident to one skilled in the art.

For example, the embodiments of the present invention can be modified as follows. The planar precision of the contact face 22 in the abovementioned embodiment is 30 microns or less. Specifically, the BOW and WARP are respectively 30 microns or less.

The BOW is indicative of a difference of a center face of the single crystalline wafer 50 from a reference face. The WARP is indicative of a difference between a maximum value and a minimum value of a distance from a reference face (a best fit reference face) of a center face having compensated for a deformation component clue to a self-weight up to a center face of the single crystalline wafer 50, in a state in which the contact face 22 is neither adsorbed nor fixed.

However, the planer precision of the contact face 22 can be modified according to an outer diameter and a thickness of the single crystalline wafer 50 without being limitative thereto. For example, a single crystalline wafer, which is identical in outer diameter to the single crystalline wafer 50, and which is greater in thickness than that of the single crystalline wafer 50, is unlikely to be deformed. Thus, in a case where the thickness of the single crystalline wafer 50 is increased, further high planar precision is required for the contact face 22. On the other hand, a single crystalline wafer, which is identical in outer diameter to the single crystalline wafer 50, and is smaller in thickness than the single crystalline wafer 50, is likely to be deformed. Therefore, in a case where the thickness of the single crystalline wafer 50 is decreased, the planer precision required for the contact face 22 is loosened.

While the supporting substrate 30 in the abovementioned embodiments was employed as a substrate to be bonded on the single crystalline wafer 50, the coating layer 20 may be further grown by means of a physical vapor deposition method or a chemical vapor deposition method without being limitative thereto. According to this supporting substrate, the supporting substrate 30 and the single crystalline wafer 50 do not need to be bonded with each other, and in the bonding process, entry of impurities or the like between the supporting substrate 30 and the single crystalline wafer 50 can be prevented.

The abovementioned coating layer 20 in the embodiment may be formed of a material suitable for a structure of the single crystalline wafer 50 without being limitative to silicon carbide or silicon.

The abovementioned silicon carbide polycrystalline substrate 10 in the embodiment may be formed of a material suitable for a structure or the like of the coating layer 20 or the single crystalline wafer 50 without being limitative to a polycrystalline body consisting of silicon carbide.

In this manner, of course, the present invention includes a variety of embodiments or the like which are not described herein. Therefore, technical scope of the present invention is defined by only specific matters of the invention according to the claims that are reasonable from the foregoing description.

The entire contents of JP-A-2009-085294 (filed on Mar. 31, 2009) are incorporated in the present specification by reference.

### INDUSTRIAL APPLICABILITY

According to the present invention, in a case where a wafer and a substrate are used while they are bonded with each other, since a gap between the wafer and the substrate can be reduced, and the bonding strength can be increased, the present invention is applicable to a bonded substrate obtained by bonding a supporting substrate on a thin-filmed single crystalline wafer in order to ensure the strength of the thin-filmed single crystalline wafer.

### DESCRIPTION OF REFERENCE NUMERAL

10 . . . silicon carbide polycrystalline substrate, 20 . . . coating layer, 22 . . . contact face, 24 . . . evaporation face, 30 . . . supporting substrate, 50 . . . single crystalline wafer, 100 . . . bonded substrate

1. A supporting substrate to be bonded on a single crystalline wafer made of a single crystalline body, the supporting substrate comprising:
a silicon carbide polycrystalline substrate made of a silicon carbide polycrystalline body; and
a coating layer to be evaporated on the silicon carbide polycrystalline body, wherein
the coating layer is made of silicon carbide or silicon, and comes into contact with the single crystalline wafer, and
an arithmetic average roughness of a surface of the coating layer that comes into contact with the single crystalline wafer is 1 nanometer or less.

2. The supporting substrate according to claim 1, wherein
the coating layer is evaporated on the silicon carbide polycrystalline substrate by means of a physical vapor deposition method or a chemical vapor deposition method.

3. The supporting substrate according to claim 1, wherein a thickness of the coating layer is 5 microns or more.

4. A bonded substrate comprising:
a single crystalline wafer made of a single crystalline body; and
a supporting substrate to be bonded on the single crystalline wafer,
wherein the supporting substrate has: a silicon carbide polycrystalline substrate made of a silicon carbide polycrystalline body; and a coating layer to be evaporated on the silicon carbide polycrystalline substrate,
the coating layer is made of silicon carbide or silicon, and comes into contact with the single crystalline wafer, and
an arithmetic average roughness of a surface of the coating layer that comes into contact with the single crystalline wafer is 1 nanometer or less.

5. A method for manufacturing a supporting substrate to be bonded on a single crystalline wafer made of a single crystalline body, the method comprising the steps of:
evaporating silicon carbide or silicon on a silicon carbide polycrystalline substrate made of a silicon carbide polycrystalline body; and
applying grinding onto a face onto which the evaporation is made, in the silicon carbide polycrystalline substrate, so as to allow an arithmetic average roughness of the evaporated face to be 1 nanometer or less.

6. A method for manufacturing a bonded substrate which has a single crystalline wafer made of a single crystalline body and a supporting substrate to be bonded on the single crystalline wafer, the method comprising the steps of:
evaporating silicon carbide or silicon on a silicon carbide polycrystalline substrate made of a silicon carbide polycrystalline body;
applying grinding onto a face onto which the evaporation is made, in the silicon carbide polycrystalline substrate, so as to allow an arithmetic average roughness of the evaporated face to be 1 nanometer or less; and
bonding a face to which the grinding is applied and the single crystalline wafer with each other.

7. The supporting substrate according to claim 2, wherein a thickness of the coating layer is 5 microns or more.
